(19) United States
(12) Patent Application Publication
(10) Pub. No.: US 2016/0330836 A1
(43) Pub. Date: Nov. 10, 2016

(54) PRINTED WIRING BOARD

(71) Applicant: IBIDEN CO., LTD., Ogaki (JP)

(72) Inventors: Ryota MIZUTANI, Ogaki (JP); Satoru Kawai, Ogaki (JP)

(73) Assignee: IBIDEN CO., LTD., Ogaki (JP)

(21) Appl. No.: 15/141,308

(22) Filed: Apr. 28, 2016

(30) Foreign Application Priority Data
May 7, 2015 (JP) 2015-094704

(51) Int. Cl. H05K 1/11; H05K 3/42; H05K 1/09; H05K 3/00

(52) U.S. Cl. CPC H05K 1/115; H05K 3/0032; H05K 3/424; H05K 3/422; H05K 1/09

(57) ABSTRACT

A method for manufacturing a printed wiring board includes forming a through hole in an insulating substrate such that the through hole penetrates through the substrate and has first tapered hole, second tapered hole and minimum diameter portion connecting the first and second tapered holes at a position displaced toward first or second surface of the substrate from a mid-point of the through hole in thickness direction of the substrate, and applying electrolytic plating to the substrate while flowing an electrolytic plating solution including a deposition inhibitor into the through hole from the first and second tapered holes and increasing an amount of the inhibitor adsorbing to electrolytic metal plating depositing at the minimum diameter portion such that electrolytic metal plating forms a closed portion closing the through hole substantially at the mid-point and fills the first and second tapered holes to form a through-hole conductor in the through hole.

### CROSS-REFERENCE TO RELATED APPLICATIONS

The present application is based upon and claims the benefit of priority to Japanese Patent Application No. 2015-094704, filed May 7, 2015, the entire contents of which are incorporated herein by reference.

### BACKGROUND OF THE INVENTION

1. Field of the Invention

The invention relates to a printed wiring board having a through-hole conductor.

2. Description of Background Art

Japanese Patent Laid-Open Publication No. 2003-046248 describes forming a substantially hourglass-shaped through hole for a through-hole conductor in a resin substrate as an insulating substrate by communicatively connecting, at a thickness direction mid-point of the resin substrate, top portions of tapered holes that are respectively formed from both sides of the resin substrate, and filling the through hole with copper plating by electrolytic plating. In Japanese Patent Laid-Open Publication No. 2003-046248, by closing the through hole with copper plating starting from a minimum diameter part of the through hole, the minimum diameter part being positioned at the thickness direction mid-point of the resin substrate, the entire through hole for a through-hole conductor is filled with copper plating and a through-hole conductor is formed. The entire contents of this publication are incorporated herein by reference.

### SUMMARY OF THE INVENTION

According to one aspect of the present invention, a method for manufacturing a printed wiring board includes forming a through hole in an insulating substrate such that the through hole penetrates through the insulating substrate and has a first tapered hole, a second tapered hole and a minimum diameter portion connecting the first tapered hole and the second tapered hole at a position displaced toward one of a first surface and a second surface of the insulating substrate from a mid-point of the through hole in a thickness direction of the insulating substrate, and applying electrolytic plating to the insulating substrate while flowing an electrolytic plating solution including a deposition inhibitor into the through hole from the first tapered hole and second tapered hole of the through hole and increasing an amount of the deposition inhibitor adsorbing to electrolytic metal plating depositing at the minimum diameter portion such that electrolytic metal plating forms a closed portion closing the through hole substantially at the mid-point of the through hole and fills the first tapered hole and second tapered hole of the through hole to form a through-hole conductor including the electrolytic metal plating in the through hole.

According to another aspect of the present invention, a printed wiring board includes an insulating substrate having a through hole, a first conductor layer on a first surface of the insulating substrate and including electrolytic metal plating, a second conductor layer formed on a second surface of the insulating substrate on the opposite side with respect to the first surface of the insulating substrate and including the electrolytic meal plating, and a through-hole conductor formed in the through hole in the insulating substrate and including the electrolytic metal plating filling the through hole such that the through-hole conductor electrically connects the first conductor layer and the second conductor layer and has a closed portion closing the through hole substantially at a mid-point of the through hole in a thickness direction of the insulating substrate. The through hole has a first tapered hole, a second tapered hole and a minimum diameter portion connecting the first tapered hole and the second tapered hole at a position displaced toward one of the first surface and the second surface of the insulating substrate from the mid-point of the through hole.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A-1E are cross-sectional views that sequentially illustrate processes for manufacturing a printed wiring board of an embodiment of the present invention;

FIGS. 2A and 2B are cross-sectional views that respectively schematically illustrate a through-hole conductor during a formation process of the printed wiring board of the embodiment and a formed through-hole conductor;

FIGS. 3A and 3B are cross-sectional views that sequentially illustrate processes for forming the through-hole conductor of the printed wiring board of the embodiment;

FIGS. 4A and 4B are cross-sectional views that respectively schematically illustrate a through-hole conductor during a formation process of an example of a conventional printed wiring board and a formed through-hole conductor;

FIGS. 5A and 5B are cross-sectional views that sequentially illustrate processes for forming the through-hole conductor of the conventional printed wiring board of the example; and

FIG. 6 is a cross-sectional view schematically illustrating a through-hole conductor during a formation process of a printed wiring board of another embodiment of the present invention.

### DETAILED DESCRIPTION OF THE EMBODIMENTS

The embodiments will now be described with reference to the accompanying drawings, wherein like reference numerals designate corresponding or identical elements throughout the various drawings.

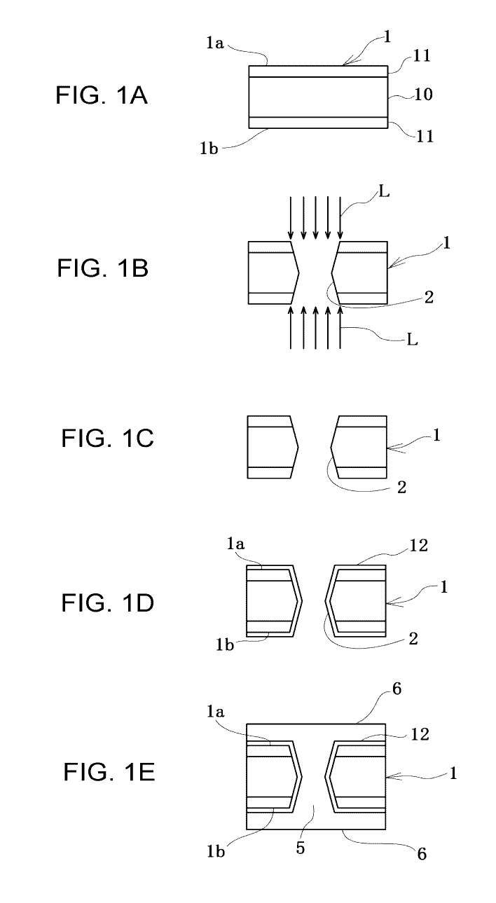

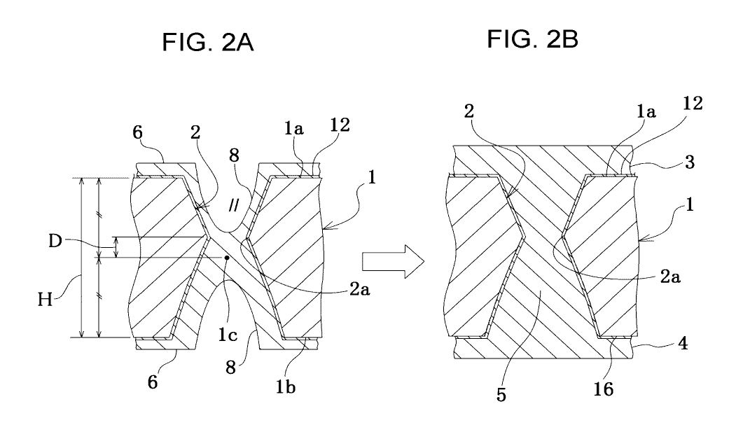

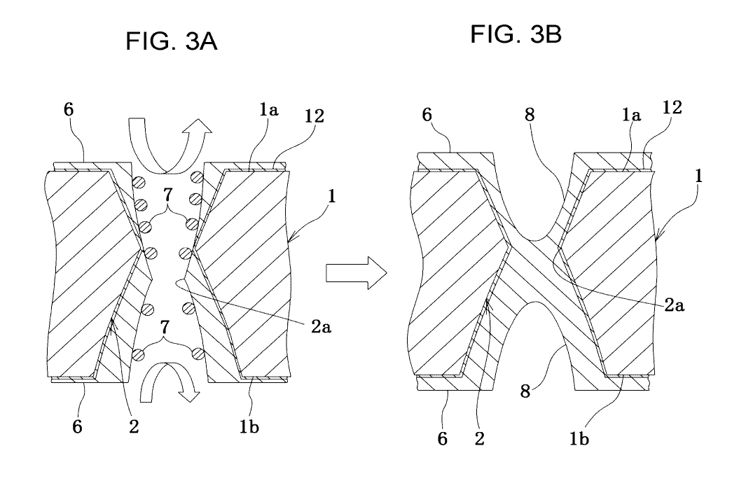

In the following, first, a printed wiring board of an embodiment of the present invention is described in detail. Here, FIG. 1A-1E are cross-sectional views that sequentially illustrate processes for manufacturing a printed wiring board of an embodiment of the present invention. FIGS. 2A and 2B are cross-sectional views that respectively schematically illustrate a through-hole conductor during a formation process of the printed wiring board of the embodiment and the formed through-hole conductor. FIGS. 3A and 3B are cross-sectional views that sequentially illustrate processes for forming the through-hole conductor of the printed wiring board of the embodiment.

The printed wiring board of the present embodiment includes an insulating substrate 1. As illustrated in FIG. 2B, the insulating substrate 1 has a first surface (1a) that faces upward in FIG. 2B, and a second surface (1b) that is on an opposite side of the first surface (1a) and faces downward in FIG. 2B, and has a through hole 2 for a through-hole conductor that extends between the first surface (1a) and the second surface (1b). The through hole 2 has substantially an hourglass shape that is formed by communicatively connecting top portions of tapered holes that are respectively formed from the first surface (1a) and the second surface (1b) of the insulating substrate 1. In the present embodiment, as illustrated in FIG. 2A, a minimum diameter part (2a) of the through hole 2 in the illustrated example is displaced by a distance (D) from a thickness direction mid-point (1c) of the insulating substrate 1 toward the first surface (1a). It is preferable that a relation between the amount (D) by which the minimum diameter part (2a) of the through hole 2 is displaced from the thickness direction mid-point (1c) of the insulating substrate 1 and a thickness (H) of the insulating substrate 1 be 0<D/H<0.4, that is, the displacement amount (D) be less than 40% of the thickness (H). This is because, when the displacement amount (D) is 40% or more of the thickness (H), during formation of a through-hole conductor 5 (to be described later), it may be difficult to close the through hole 2 by electrolytic copper plating from a vicinity of the thickness direction mid-point (1c) of the insulating substrate 1 deeper than the minimum diameter part (2a) of the through hole 2.

The printed wiring board of the present embodiment further includes: a first conductor layer 3 that is formed on the first surface (1a) of the insulating substrate 1 by copper plating; a second conductor layer 4 that is formed on the second surface (1b) of the insulating substrate 1 by copper plating; and a through-hole conductor 5 that is formed from copper plating filled in the through hole 2, and electrically connects the first conductor layer 3 and the second conductor layer 4.

When the printed wiring board of the present embodiment is manufactured, first, as illustrated in FIG. 1A, the insulating substrate 1 is prepared. As the insulating substrate 1, for example, ab epoxy resin substrate, a silicon substrate, a glass substrate, or the like, can be used. Preferably, for example, a double-sided copper-clad resin substrate obtained by pasting a copper foil 11 on both sides of a resin substrate 10 is used. As the resin substrate 10, for example, a prepreg obtained by impregnating a core material such as glass fiber with resin and having a thermal expansion coefficient of 1-15 ppm/° C. in an extension direction can be used. This is because, when such a prepreg is used, excessive deformation or dimensional change due to heat is unlikely to occur in a printed substrate.

Next, as illustrated in FIG. 1B, the substantially hourglass-shaped through hole 2 for a through-hole conductor that extends between the first surface (1a) and the second surface (1b) of the insulating substrate 1 is formed in the insulating substrate 1. As illustrated in FIG. 1B, such a substantially hourglass-shaped through hole can be formed by connecting top portions of tapered holes that are formed, for example, by laser (L) at substantially the positions on the first surface (1a) and the second surface (1b) of the insulating substrate 1. However, due to a different in laser (L) output or the like between the first surface (1a) side and the second surface (1b) side, as described above, the minimum diameter part (2a) of the through hole 2 is displaced by a distance (D) from the thickness direction mid-point (1c) of the insulating substrate 1 toward the first surface (1a).

Next, as illustrated in FIG. 1C, a normal desmear treatment is performed to remove smear in the through hole 2. Next, as illustrated in FIG. 1D, the first surface (1a) and the second surface (1b) of the insulating substrate 1 and a side wall of the through hole 2 are subjected to a roughening treatment, and thereafter, an electroless copper plating film 12 is integrally formed thereon.

Further, as illustrated in FIG. 1E, a copper plating layer 6 is formed by electrolytic copper plating on the electroless copper plating film 12 on the first surface (1a) of the insulating substrate 1, and an electrolytic copper plating layer 6 is formed by electrolytic copper plating on the electroless copper plating film 12 on the second surface (1b) of the insulating substrate 1. At the same time, as sequentially illustrated in FIGS. 2A and 2B, the through-hole conductor 5 that electrically connects the electrolytic copper plating layer 6 on the first surface (1a) and the electrolytic copper plating layer 6 on the second surface (1b) is filled and formed in the through hole 2 on the electroless copper plating film 12 by electrolytic copper plating.

In this way, when the through-hole conductor 5 is filled and formed in the through hole 2 by electrolytic copper plating, the insulating substrate 1 is immersed in an electrolytic plating solution containing a deposition inhibitor, and electrolytic copper plating is performed on the electroless copper plating film 12 using the electroless copper plating film 12 as one electrode, while as illustrated by arrows in FIG. 3A, among the first surface (1a) side and the second surface (1b) side of the insulating substrate 1, the electrolytic plating solution is stirred more strongly on the first surface (1a) side that is closer to the minimum diameter part (2a) of the through hole 2 than on the second surface (1b) side. Thereby, the copper plating layers 6 are respectively formed on the first surface (1a) and the second surface (1b), and the through-hole conductor 5 that electrically connects the copper plating layer 6 on the first surface (1a) and the copper plating layer 6 on the second surface (1b) is formed in the through hole 2.

Electrolytic copper plating has a tendency of depositing on a corner part of a plating object. Copper plating deposited on an inlet corner part of the through hole 2 is likely to interfere with filling of the copper plating into the through hole 2. A deposition inhibitor (deposited metal growth inhibitor) suppresses this tendency and allows the electrolytic copper plating to be filled into the interior of the through hole 2. As the deposition inhibitor, for example, a metal particle dispersant or the like can be used that adsorbs on a surface of a deposited metal when the deposited metal becomes large and slows the growth of the deposited metal.

As a result, as illustrated in FIGS. 2A, 3A and 3B, in the through hole 2, copper plating starting to deposit from the side wall of the through hole 2 toward a central axis. In this case, due to the above-described difference in stirring strength, the first surface (1a) side has more deposition inhibitor 7 adsorbed on the copper plating surface than the second surface (1b) side has, so that it is more difficult for the copper plating to deposit on the first surface (1a) side. Therefore, the through hole 2 is first closed by the copper plating at a position that is deeper than the minimum diameter part (2a) of the insulating substrate 1 and is near the thickness direction mid-point (1c) of the through hole 2. Then, copper plating is gradually filled in recesses 8 that are formed by closing the through hole 2 at the position near the thickness direction mid-point (1c) and have about the same depth on the first surface (1a) side and the second surface (1b) side and, as illustrated in FIG. 2B, the through-hole conductor 5 without any void is formed.

Thereafter, predetermined wiring patterns are formed using a pattern formation method such as etching in the electroless copper plating film 12 and the electrolytic copper plating layers 6 that are formed on the first surface (1a) and the second surface (1b) of the insulating substrate 1. Thereby, as illustrated in FIG. 2B, the first conductor layer 3 and the second conductor layer 4 are formed that each include two copper plating layers, that is, the electroless copper plating film 12 and the electrolytic copper plating layer 6, and the printed wiring board of the present embodiment is manufactured.

Therefore, according to the printed wiring board of the present embodiment, even when the tapered holes on the first surface (1a) side and the second surface (1b) side of the insulating substrate 1 are slightly different in central axis position, inner diameter, depth and the like, a cross-sectional shape of the through hole 2 is not vertically symmetrical with respect to the thickness direction mid-point (1c) of the insulating substrate 1, and the minimum diameter part (2a) of the through hole 2 is displaced from the thickness direction mid-point (1c) of the insulating substrate 1 toward the first surface (1a), as illustrated in FIG. 2B, a void does not remain in the through-hole conductor 5 that electrically connects the first conductor layer 3 on the first surface (1a) and the second conductor layer 4 on the second surface (1b). Therefore, reliability of the through-hole conductor 5 can be increased.

Also when the minimum diameter part (2a) of the through hole 2 is displaced from the thickness direction mid-point (1c) of the insulating substrate 1 toward the second surface (1b), in the same manner as described above, the through-hole conductor 5 that electrically connects the first conductor layer 3 on the first surface (1a) and the second conductor layer 4 on the second surface (1b) can be formed such that a void does not remain in the through-hole conductor 5.

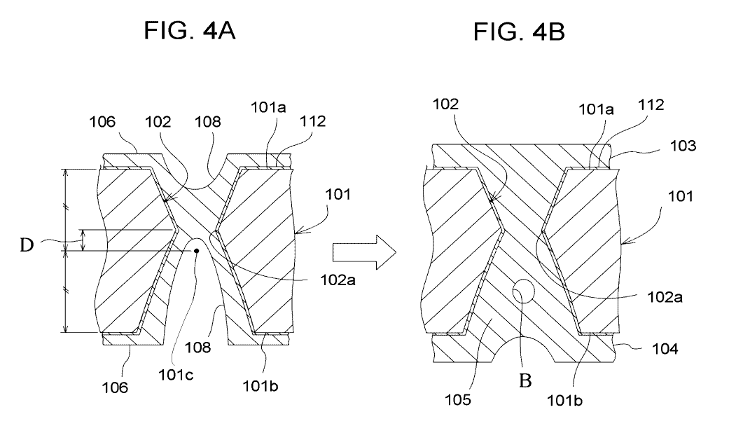

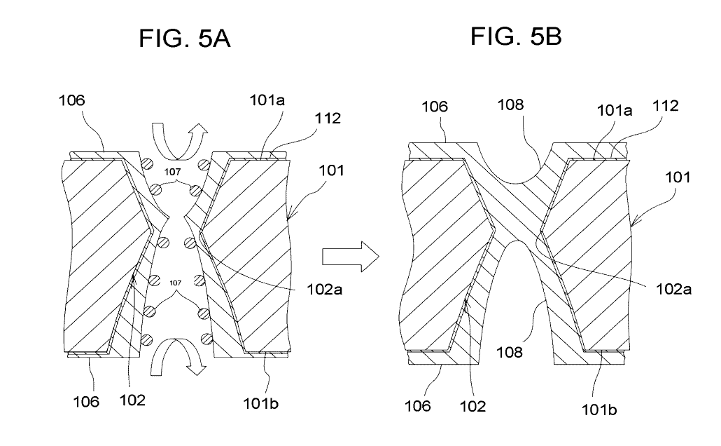

Next, an example of a conventional printed wiring board is described in detail. FIGS. 4A and 4B are cross-sectional views that respectively schematically illustrate a through-hole conductor during a formation process of the conventional printed wiring board of the example and the formed through-hole conductor. FIGS. 5A and 5B are cross-sectional views that sequentially illustrate processes for forming the through-hole conductor of the conventional printed wiring board of the example.

The conventional printed wiring board of the example includes an insulating substrate 101. As illustrated in FIGS. 4A and 4B, the insulating substrate 101 has a first surface (101a) that faces upward in the drawings, and a second surface (101b) that is on the opposite side of the first surface (101a) and faces downward in drawings, and a through hole 102 for a through-hole conductor that extends between the first surface (101a) and the second surface (101b). The through hole 102 has substantially an hourglass shape that is formed by communicatively connecting top portions of tapered holes that are respectively formed from the first surface (101a) and the second surface (101b) of the insulating substrate 101. A minimum diameter part (102a) of the through hole 102 in the illustrated example is displaced from a thickness direction mid-point (101c) of the insulating substrate 101 toward the first surface.

The conventional printed wiring board of the example further includes: a first conductor layer 103 that is formed on the first surface (101a) of the insulating substrate 101 by copper plating; a second conductor layer 104 that is formed on the second surface (101b) of the insulating substrate 101 by copper plating; and a through-hole conductor 105 that is formed from copper plating filled in the through hole 102, and electrically connects the first conductor layer 103 and the second conductor layer 104.

In the conventional printed wiring board of the example, when the through-hole conductor 105 is filled and formed in the through hole 102 by copper plating, the first surface (101a) and the second surface (101b) of the insulating substrate 101 and a side wall of the through hole 102 are first subjected to a roughening treatment, and then a copper plating film 112 is formed thereon by electroless plating.

Next, the insulating substrate 101 is immersed in an electrolytic plating solution containing a deposition inhibitor, and electrolytic copper plating is performed on the electroless copper plating film using the electroless copper plating film as one electrode while, as illustrated by arrows in FIG. 5A, the electrolytic plating solution is stirred with about the same strength on the first surface (101a) side and the second surface (101b) side of the insulating substrate 101. Thereby, a copper plating layer 106 is formed on each of the first surface (101a) and the second surface (101b) and the through-hole conductor 105 is formed in the through hole 102.

As a result, as illustrated in FIGS. 4A and 5B, in the through hole 102, copper plating starting to deposit from the side wall of the through hole 102 toward a central axis, and the through hole 102 is first closed by the copper plating at a position near the minimum diameter part (102a) of the through hole 102. Then, copper plating is gradually filled in recesses 108 that are formed by closing the through hole 102 at the position near the minimum diameter part (102a) and have different depths on the first surface (101a) side and on the second surface (101b) side and, as illustrated in FIG. 4B, the through-hole conductor 105 is formed in which a void (B) remains on the second surface (101b) side, that is, the side where the recess 8 is deeper.

Thereafter, predetermined wiring patterns are formed using a pattern formation method such as etching in the electroless copper plating film 112 and the electrolytic copper plating layers 106 that are formed on the first surface (101a) and the second surface (101b) of the insulating substrate 101. Thereby, as illustrated in FIG. 4B, the first conductor layer 103 and the second conductor layer 104 are formed that each include two copper plating layers, that is, the electroless copper plating film 112 and the electrolytic copper plating layer 106, and the conventional printed wiring board is manufactured.

Therefore, in the conventional printed wiring board of the example, as illustrated in FIG. 4B, the void (B) remains on the second surface (101b) side of the insulating substrate 101 in the through-hole conductor 105, and reliability of the through-hole conductor is reduced.

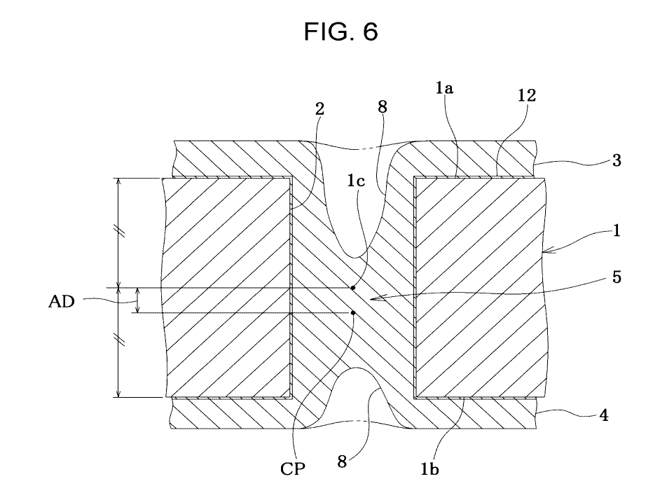

FIG. 6 is a cross-sectional view schematically illustrating a through-hole conductor during a formation process of a printed wiring board according to another embodiment of the present invention. The printed wiring board of the present embodiment is different from the previous embodiment only in that a through hole for a through-hole conductor in an insulating substrate is not a substantially hourglass-shaped hole having a constricted portion as in the previous embodiment, but is a so-called straight hole having a constant inner diameter along an axial direction, and has the same structures as the previous embodiment in other respects. Therefore, in FIG. 6, portions that are the same as in the previous embodiment are indicated using the same reference numeral symbols.

That is, the printed wiring board of the present embodiment also includes an insulating substrate 1. As illustrated in FIG. 6, the insulating substrate 1 has a first surface (1a) that faces upward in FIG. 6, and a second surface (1b) that is on an opposite side of the first surface (1a) and faces downward in FIG. 6, and has a through hole 2 for a through-hole conductor that extends between the first surface (1a) and the second surface (1b).

The through hole 2 is a straight hole that has a constant inner diameter along the axial direction. Such a straight through hole 2 can be formed, for example, using a drill to drill from the first surface (1a) side or the second surface (1b) side of the insulating substrate 1.

As illustrated in FIG. 6, the printed wiring board of the present embodiment further includes: a first conductor layer 3 that is formed on the first surface (1a) of the insulating substrate 1 by copper plating; a second conductor layer 4 that is formed on the second surface (1b) of the insulating substrate 1 by copper plating; and a through-hole conductor that is formed from copper plating that is filled in the through hole 2 by electrolytic plating, and electrically connects the first conductor layer 3 and the second conductor layer 4.

In the printed wiring board of the present embodiment, during a formation process of the through-hole conductor 5, when copper plating is filled in the through hole 2 by electrolytic plating, the first surface (1a) and the second surface (1b) of the insulating substrate 1 and a side wall of the through hole 2 are first subjected to a roughening treatment, and then a copper plating film (not illustrated in FIG. 6) is integrally formed thereon by electroless plating.

Next, the insulating substrate 1 is immersed in an electrolytic plating solution containing a deposition inhibitor, and electrolytic copper plating is performed on the electroless copper plating film using the electroless copper plating film as one electrode. Thereby, a copper plating layer 6 is formed on each of the first surface (1a) and the second surface (1b) of the insulating substrate 1 and the through-hole conductor 5 that electrically connects the copper plating layers 6 on the first surface (1a) and the second surface (1b) is formed in the through hole 2.

During the electrolytic copper plating, similar to the previous embodiment, among the first surface (1a) side and the second surface (1b) side of the insulating substrate 1, when the electrolytic plating solution is stirred more strongly on the first surface (1a) side than on the second surface (1b) side, due to the difference in stirring strength, the first surface (1a) side has more deposition inhibitor 7 adsorbed on the copper plating surface than the second surface (1b) side has, so that it is more difficult for the copper plating to deposit on the first surface (1a) side. Therefore, as indicated by solid lines in FIG. 6, the through hole 2 is first closed by the copper plating at a position (CP) that is displaced by an arbitrary distance (AD) from a thickness direction mid-point (1c) of the insulating substrate 1 in the through hole 2 toward the second surface (1b). Then, as illustrated by imaginary lines in FIG. 6, copper plating is gradually filled in recesses 8 that are formed by closing the through hole 2 at the position (CP) closer to the second surface (1b) and have different depths on the first surface (1a) side and on the second surface (1b) side, and the through-hole conductor 5 without any void is formed in the through hole 2.

It is also possible that, during the electrolytic copper plating, opposite to the previous embodiment, among the first surface (1a) side and the second surface (1b) side of the insulating substrate 1, by stirring the electrolytic plating solution more strongly on the second surface (1b) side than on the first surface (1a) side, the through hole 2 is first closed by the copper plating at a position (CP) that is displaced by an arbitrary distance (AD) from the thickness direction mid-point (1c) of the insulating substrate 1 in the through hole 2 toward the first surface (1a).

Thereafter, predetermined wiring patterns are formed using a pattern formation method such as etching in the copper plating layers 6 that are formed on the first surface (1a) and the second surface (1b) of the insulating substrate 1. Thereby, the first conductor layer 3 and the second conductor layer 4 are formed, and the first conductor layer 3 and the second conductor layer 4 are electrically connected by the through-hole conductor 5.

Therefore, according to the printed wiring board of the present embodiment, as illustrated in FIG. 6, even in the case where the through hole 2 is a straight hole that does not have a constricted portion in the middle, a void does not remain in the through-hole conductor 5 that electrically connects the first conductor layer 3 on the first surface (1a) and the second conductor layer 4 on the second surface (1b). Therefore, reliability of the through-hole conductor 5 cam be increased.

In addition, the through hole 2 is first closed by electrolytic copper plating at a position that is displaced by an arbitrary distance (AD) from the thickness direction mid-point (1c) of the insulating substrate 1 in the through hole 2 toward the first surface (1a) or the second surface (1b) of the insulating substrate 1. Thereby, the recesses 8 having different depths on the first surface (1a) side and on the second surface (1b) side can be appropriately filled by electrolytic copper plating. Therefore, recesses having different arbitrary depths on the first surface (1a) side and on the second surface (1b) side can be formed on surfaces of the through-hole conductor 5. In this case, it is preferable that the depths of the recesses on the surfaces of the through-hole conductor 5 be less than 7 μm. When the depths of the recesses are 7 μm or more, it is possible that flatness of surfaces of insulating resin layers that are layer laminated on the recesses in order to form the multilayer printed wiring board is excessively impaired.

The above-described printed wiring boards of the embodiments that are illustrated in FIGS. 2A and 2B and FIG. 6 can each be used as a core substrate or the like in a multilayer printed board that forms a normal electronic circuit, and in addition, can also be each used as a core substrate or the like in a printed wiring board of a package on package (POP) type in which an upper side package substrate (on which a semiconductor element is mounted) is laminated on and electrically connected to a lower side package substrate (on which a semiconductor element is mounted).

In the printed wiring boards of the embodiments that are illustrated in FIGS. 2A and 2B and FIG. 6, the first conductor layer 3 on the first surface (1a) and the second conductor layer 4 on the second surface (1b) are each formed by an electroless copper plating film and an electrolytic copper plating layer on the electroless copper plating film. However, it is also possible that, in an embodiment of the present invention, as the insulating substrate 1, for example, as illustrated in FIG. 1A-1E, the double-sided copper-clad substrate in which the copper foil 11 is pasted on both surfaces of the resin substrate 10 is used, and the first conductor layer 3 and the second conductor layer 4 are each formed by the electroless copper plating film 12 on the copper foil 11 and the electrolytic copper plating layer 6 on the electroless copper plating film 12.

Further, in the printed wiring boards of the embodiments that are illustrated in FIGS. 2A and 2B and FIG. 6, the electrolytic plating that forms the first conductor layer 3 on the first surface (1a), the second conductor layer 4 on the second surface (1b) and the through-hole conductor 5 in the through hole 2 is electrolytic copper plating. However, in an embodiment of the present invention, electrolytic plating of other metals may also be adopted.

Thus, according to a printed wiring board according to an embodiment of the present invention, regardless of a position of a constricted portion or presence or absence of a constricted portion in a through hole, it is possible that the through hole is first closed by electrolytic plating at an arbitrary position in the through hole, and a void is prevented from remaining in a through-hole conductor.

The minimum diameter part of the through hole for a through-hole conductor may be displaced from the thickness direction mid-point of the resin substrate toward one surface. In this case, when the through hole is closed with copper plating starting from the minimum diameter part, a void may remain in copper plating starting to fill from the other surface side. Therefore, reliability of a through-hole conductor formed by filling a through hole for a through-hole conductor with copper plating is likely to be reduced.

A printed wiring board according to an embodiment of the present invention increase reliability of a through-hole conductor.

A printed wiring board according to an embodiment of the present invention includes an insulating substrate that has a first surface and a second surface that is on the opposite side of the first surface, and has a through hole for a through-hole conductor that extends between the first surface and the second surface, a first conductor layer that is formed on the first surface of the insulating substrate, a second conductor layer that is formed on the second surface of the insulating substrate; and a through-hole conductor that is formed in the through hole from metal plating that is filled in the through hole by electrolytic plating by closing the through hole from an arbitrary position in a thickness direction of the insulating substrate, and electrically connects the first conductor layer and the second conductor layer.

The through hole has a substantially hourglass shape that is formed by communicatively connecting top portions of tapered holes that are respectively formed from the first surface and the second surface. When a minimum diameter part of the through hole is at a position that is displaced from a thickness direction mid-point of the insulating substrate toward either one of the first surface and the second surface, it is preferable that the through-hole conductor be formed in the through hole from metal plating that is filled in the through hole by electrolytic plating by closing the through hole starting from the thickness direction mid-point of the insulating substrate.

Further, it is preferable that the tapered holes be formed using laser.

The metal plating may be substantially filled in the entire through hole. Therefore, the through-hole conductor may have a recess on a surface on a side of at least one of the first surface and the second surface of the insulating substrate.

Obviously, numerous modifications and variations of the present invention are possible in light of the above teachings. It is therefore to be understood that within the scope of the appended claims, the invention may be practiced otherwise than as specifically described herein.

What is claimed is:

1. A method for manufacturing a printed wiring board, comprising:
forming a through hole in an insulating substrate such that the through hole penetrates through the insulating substrate and has a first tapered hole, a second tapered hole and a minimum diameter portion connecting the first tapered hole and the second tapered hole at a position displaced toward one of a first surface and a second surface of the insulating substrate from a mid-point of the through hole in a thickness direction of the insulating substrate; and
applying electrolytic plating to the insulating substrate while flowing an electrolytic plating solution including a deposition inhibitor into the through hole from the first tapered hole and second tapered hole of the through hole and increasing an amount of the deposition inhibitor adsorbing to electrolytic metal plating depositing at the minimum diameter portion such that electrolytic metal plating forms a closed portion closing the through hole substantially at the mid-point of the through hole and fills the first tapered hole and second tapered hole of the through hole to form a through-hole conductor comprising the electrolytic metal plating in the through hole.

2. A method for manufacturing a printed wiring board according to claim 1, wherein the applying of the electrolytic plating comprises immersing the insulating substrate in the electrolytic plating solution, and stirring the electrolytic plating solution at different strengths between a first surface side and a second surface side of the insulating substrate.

3. A method for manufacturing a printed wiring board according to claim 1, wherein the applying of the electrolytic plating comprises immersing the insulating substrate in the electrolytic plating solution, and stirring the electrolytic plating solution at different strengths between a first surface side and a second surface side of the insulating substrate such that the electrolytic plating solution is stirred at a greater strength on one of the first surface and the second surface of the insulating substrate toward which the minimum diameter portion of the through hole is displaced.

4. A method for manufacturing a printed wiring board according to claim 1, wherein the forming of the through hole comprises setting the position of the minimum diameter portion such that the position of the minimum diameter portion is displaced by a displacement amount satisfying 0<D/H<0.4, where D represents the displacement amount and H represents a thickness of the insulating substrate.

5. A method for manufacturing a printed wiring board according to claim 1, wherein the forming of the through hole comprises applying laser upon the insulating substrate from the first surface and second surface of the insulating substrate such that the through hole is formed to have the minimum diameter portion at the position.

6. A method for manufacturing a printed wiring board according to claim 1, wherein the applying of the electrolytic plating comprises immersing the insulating substrate in the electrolytic plating solution.

7. A method for manufacturing a printed wiring board according to claim 1, wherein the applying of the electrolytic plating comprises forming a recess on at least one of a first end surface and a second end surface of the through-hole conductor.

8. A method for manufacturing a printed wiring board according to claim 1, wherein the applying of the electrolytic plating comprises forming a recess on at least one of a first end surface and a second end surface of the through-hole conductor such that the recess has a depth of less than 7 μm.

9. A method for manufacturing a printed wiring board according to claim 1, wherein the applying of the electrolytic plating comprises forming a first recess on a first end surface of the through-hole conductor and a second recess on a second end surface of the through-hole conductor such that the first and second recesses have different depths with respect to each other.

10. A method for manufacturing a printed wiring board according to claim 1, wherein the applying of the electrolytic plating comprises forming a first recess on a first end surface of the through-hole conductor and a second recess on a second end surface of the through-hole conductor such that the first and second recesses have different depths with respect to each other and that the depths of the first and second recesses are less than 7 μm, respectively.

11. A method for manufacturing a printed wiring board according to claim 1, further comprising:
applying electroless plating on the insulating substrate such that electroless metal plating is deposited inside the through hole and on the first surface and second surface of the insulating substrate prior to the applying of the electrolytic plating,
wherein the applying of the electrolytic plating comprises applying the electrolytic plating such that a first conductor layer comprising the electroless metal plating and the electrolytic metal plating is formed on the first surface of the insulating substrate, a second conductor layer comprising the electroless metal plating and the metal plating is formed on the second surface of the insulating substrate, and the through-hole conductor comprising the electroless metal plating and the metal plating is formed in the through hole in the insulating substrate.

12. A method for manufacturing a printed wiring board according to claim 1, further comprising:
applying electroless copper plating on the insulating substrate such that electroless copper plating is deposited inside the through hole and on the first surface and second surface of the insulating substrate prior to the applying of the electrolytic plating,
wherein the applying of the electrolytic plating comprises applying electrolytic copper plating such that such that the first conductor layer comprising the electroless copper plating and the electrolytic copper plating is formed on the first surface of the insulating substrate, the second conductor layer comprising the electroless copper plating and the copper plating is formed on the second surface of the insulating substrate, and the through-hole conductor comprising the electroless copper plating and the copper plating is formed in the through hole in the insulating substrate.

13. A method for manufacturing a printed wiring board according to claim 1, wherein the resin substrate comprises a prepreg comprising a core material and resin and having a thermal expansion coefficient in a range of from 1 ppm/° C. to 15 ppm/° C. in an extension direction of the insulating substrate.

14. A printed wiring board, comprising:
an insulating substrate having a through hole;
a first conductor layer on a first surface of the insulating substrate and comprising electrolytic metal plating;
a second conductor layer formed on a second surface of the insulating substrate on an opposite side with respect to the first surface of the insulating substrate and comprising the electrolytic meal plating; and
a through-hole conductor formed in the through hole in the insulating substrate and comprising the electrolytic metal plating filling the through hole such that the through-hole conductor electrically connects the first conductor layer and the second conductor layer and has a closed portion closing the through hole substantially at a mid-point of the through hole in a thickness direction of the insulating substrate,
wherein the through hole has a first tapered hole, a second tapered hole and a minimum diameter portion connecting the first tapered hole and the second tapered hole at a position displaced toward one of the first surface and the second surface of the insulating substrate from the mid-point of the through hole.

15. A printed wiring board according to claim 14, wherein the minimum diameter portion is displaced by a displacement amount satisfying 0<D/H<0.4, where D represents the displacement amount and H represents a thickness of the insulating substrate, and the resin substrate comprises a prepreg comprising a core material and resin and having a thermal expansion coefficient in a range of from 1 ppm/° C. to 15 ppm/° C. in an extension direction of the insulating substrate.

16. A printed wiring board according to claim 14, wherein the through-hole conductor has a recess formed on at least one of a first end surface and a second end surface of the through-hole conductor.

17. A printed wiring board according to claim 14, wherein the through-hole conductor has a recess formed on at least one of a first end surface and a second end surface of the through-hole conductor such that the recess has a depth of less than 7 μm.

18. A printed wiring board according to claim 14, wherein the through-hole conductor has a first recess formed on a first end surface of the through-hole conductor and a second recess formed on a second end surface of the through-hole conductor such that the first and second recesses have different depths with respect to each other.

19. A printed wiring board according to claim 14, wherein the through-hole conductor has a first recess formed on a first end surface of the through-hole conductor and a second recess formed on a second end surface of the through-hole conductor such that the first and second recesses have different depths with respect to each other and that the depths of the first and second recesses are less than 7 μm, respectively.

20. A printed wiring board according to claim 14, wherein the electrolytic metal plating is electrolytic copper plating, and the first conductor layer comprises electroless copper plating and the electrolytic copper plating, the second conductor layer comprises the electroless copper plating and the copper plating, and the through-hole conductor comprises the electroless copper plating and the copper plating.
